(19) United States
(12) Patent Application Publication
(10) Pub. No.: US 2017/0023991 A1
(43) Pub. Date: Jan. 26, 2017

(54) Apparatus And Method For Cooling Portable Electronic Devices

(71) Applicant: James Hirschfeld, Delray Beach, FL (US)

(72) Inventor: James Hirschfeld, Delray Beach, FL (US)

(21) Appl. No.: 14/805,224

(22) Filed: Jul. 21, 2015

(51) Int. Cl. G06F 1/20; H05K 7/20

(52) U.S. Cl. CPC G06F 1/20; H05K 7/20509

(57) ABSTRACT

A removable cooling pad secured to the surface of an electronic device for extraction of heat from the device. The cooling pad is thin and sized to fit electronic devices of many sizes. The cooling pads can be fabricated in any suitable size for the electronic device in question, can be adhered to the electronic device, or can be integrated with a protective cover used by the electronic device. Further, the cooling pads are attachable to the surface of a device at a device's hot spot(s) for maximum efficiency. Alternative embodiments allow the cooling pads to be installed in covers that hold the electronic device, such that the cooling pad(s) are concealed and inconspicuous. An optional feature employs thermal strips that indicate when the electronic device is exceeding a temperature threshold.

### BACKGROUND

Technical Field

This invention relates in general to portable electronic devices. In particular, it relates to a disposable cooling pad that secures to the exterior of an electronic device, or is stored in a carrying case for an electronic device. The cooling pad provides a heat-absorbing surface that prevents the electronic device from overheating, and optionally provides a thermal strip to give a visual indication of the device's temperature.

Background of the Invention

The vast majority of people use portable electronic devices on a regular basis. Since these devices are typically battery-powered, the internal power supply often results in generation of substantial undesirable heat. In addition, while these devices provide substantial convenience and productivity advantages for individuals, they are often used in environments where it is difficult to control ambient temperature. As a result, overheating frequently causes problems for the user, such as errors, data loss, device shutdown, and even damage to the device due to overheating.

The prior art attempted to address this problem in several ways. One such attempt has been the use of supports, such as platforms, that contain integral fans that direct enhanced airflow to the bottom of the portable electronic device. These devices have several disadvantages. For example, fan based platforms typically require the platform to be plugged into a power source such as a wall outlet. As a result, portability is lost. Another disadvantage associated with this solution is that the platforms typically are designed for a specific type of electronic device. A platform designed to accommodate a particular make and model of a portable computer, such as a laptop or notebook, will often not be the correct size and configuration for a different make or model. Of course, a fan based platform system would be entirely unsuitable for devices such as a cellular phone, a tablet computer, or some other special-purpose electronic device. It would be desirable to have A method of cooling portable electronic devices that could be used across many technology platforms having different sizes and configurations, such as laptop computers, notebook computers, tablet computers, cellular telephones, portable gaming devices, and/or portable commercial electronic equipment.

Another drawback associated with the prior art is that the size and weight of fan-based cooling devices makes them inconvenient for a typical user to carry. It would be desirable to have a method of cooling a portable electronic device that is small in size and weight, such that it is convenient for users to carry.

Yet another drawback to the prior art is that these cooling devices are typically attached at all times when traveling, which is not desirable when ambient temperatures are such that heat is not a problem. It would be desirable to have a cooling device that could be easily and conveniently attached to an electronic device only when it is needed. For example, when the device is used indoors or in an air conditioned environment, cooling may not be needed, but when used in a warm environment, such as outdoors in summer, it would be useful.

An alternative to the fan-based cooling systems has been the development of systems that incorporate cold material, such as what is referred to as commercially available “blue ice” cooling block. While this provides some cooling capacity, this type of system typically provides substantial bulk and weight. In addition, once the cooling block has thawed it loses its capacity for cooling, and furthermore, it is too bulky and heavy for a user to carry multiple cooling blocks. It would be desirable to have a cooling device that is small enough and light enough such that the user could conveniently carry multiple cooling devices.

Another problem associated with the prior art is that solutions such as blue ice don't effectively provide cooling because they are not always in direct contact with the electronic device in question. It would be desirable to have a cooling mechanism that is in close proximity with the electronic device to ensure the maximum amount of heat transfer. In particular, it would be desirable to have a cooling device that can be attached to a particular location on the electronic device. For example, the cooling device would be more effective if placed near the hot spot on an electronic device rather than over a larger area that doesn't necessarily require cooling.

While the prior art has provided various solutions to the problem of overheating portable devices, the prior art solutions are typically bulky, heavy, and require either an external power source, or are only useful while the large heavy cooling block is effective. It would be desirable to have a device that will effectively cool the electronic device while having the ability to fit many types and sizes of electronic devices, while at the same time having low weight and portability.

### SUMMARY OF THE INVENTION

This invention provides a removable cooling pad that can be secured to the surface of an electronic device to extract heat from the device. The cooling pad is preferably fabricated using phase change material that has an insulation layer away from the surface in contact with the device. The surface in contact with the device is preferably fabricated with an efficient thermal conductor such as a metalized foil. Between the insulation layer and the metalized layer is a core layer of lightweight graphene nanoplatelets and polyaniline. The cooling pad is thin and sized to fit electronic devices of many sizes. Further, one or more cooling pads are attachable to the surface of a device at the device's hot spot(s) for maximum efficiency. Alternative embodiments allow the cooling pads to be installed in covers that hold the electronic device, such that the cooling pad(s) are concealed and inconspicuous. A further optional feature employs thermal strips that indicate when the electronic device is exceeding a temperature threshold.

### BRIEF DESCRIPTION OF THE DRAWINGS

FIG. 1 illustrates a bottom plan view of a preferred embodiment of a laptop computer showing a hot spot.

FIG. 2 illustrates a bottom plan view of a preferred embodiment of a laptop computer showing a cooling pad secured over the hot spot.

FIG. 3 illustrates a rear plan view of a preferred embodiment of a cellular phone with a cooling pad secured to its rear surface.

FIG. 4 illustrates another preferred embodiment showing a front view of a tablet cover with a cooling pad secured to the cover such that it is held in contact with the rear surface of the tablet when the tablet is placed in the cover.

FIG. 5 illustrates an edge view of a preferred embodiment of the cooling pad showing the layered structure.

FIG. 6 illustrates a rear plan view of a device with a thermal strip for indicating the temperature of the device.

### DETAILED DESCRIPTION OF THE PREFERRED EMBODIMENT

Prior to a discussion of the figures, a general overview of the invention will be provided. The invention provides cooling pads that can be secured to the surface of an electronic device much like a Band-Aid™ secures to an individual's skin. The cooling pads are thin and lightweight which allows multiple cooling pads to be carried for use when needed. When a user senses that the electronic device and use is running hot or beginning to overheat, the cooling pad is secured to the electronic device for the purpose of transferring heat out of the device. Likewise, a thermal strip can be attached to the device to indicate the temperature of the device. Thermal strips are well known in the art.

An additional advantage of using cooling pads that are adhered to the surface of a device is that the cooling pad can be applied to the surface at the point where heat is greatest rather then applying the pad to the entire device so that it covers areas that do not need cooling. The cooling pads provide an extended period of time to prevent electronic devices from overheating. This can be important when the device is in hostile environments, such as outdoors in hot weather.

The physical size of the cooling pad is an important advantage of the invention because it is very thin and lightweight. This allows multiple cooling pads to be carried so that the cooling time can be extended for longer periods of time. The small size of the cooling pads allows them to be conveniently carried in a computer bag, a telephone cover, a briefcase, a pocket, etc.

Another advantage of the invention is that its dimensions allow it to be integrated with covers designed for the particular electronic device without any modification of the covers.

In a preferred embodiment, the cooling pads are constructed of thermal-composites and insulation that serve to transfer excess heat from an electronic device to bring the devices temperature into its thermal operating profile range.

A preferred embodiment uses chemical cooling pads that the user activates when needed. The chemical reaction in the pads provides cooling to the electronic device when it is attached to the electronic device. An advantage of this embodiment is that it does not require any external power and requires a minimum amount of space. Preferably, the cooling pad would be 1/16 of an inch thick. However, the thickness can vary based on the amount of cooling capacity desired.

Depending on the type of electronic device being used, the surface area will vary. For example, for use on computer notebook's, laptops, and tablets, suitable sizes to cover the hotspots would cover a range of sizes. The sizes might normally be 8×10 inches, 4×6 inches, 4.5×4.5 inches, etc. The size selected by the user would depend on the particular electronic device in question. Of course, cooling pads for smaller devices such as smart phones would require less surface area to be covered. The advantage of chemical-based cooling pad is that it does not require any external power source. Once the chemical reaction is complete, and the cooling pad starts to decline in effectiveness, it can be peeled off of the electronic device and replaced with a fresh cooling pad. Being able to replace the cooling pads at will allows an electronic device to have an extended cooling period when traveling or outside of a fixed location.

In a preferred embodiment the cooling pad is fabricated using phase change material (PCM) that changes from solid to liquid and then back for the purpose of storing and releasing large amounts of thermal energy. In addition, thermal composites can be used that combine PCMs with other solid structures, such as copper mesh immersed in paraffin. PCMs have a high heat of fusion. Because of that, they change from solid to liquid based on exposure to varying levels of heat. The process of melting and solidifying at a certain temperatures allows PCMs to store and release significant amounts of thermal energy. Heat is absorbed or released when the material changes between solid and liquid states.

The preferred embodiment envisions an optional insulation layer on the surface of the cooling pad (the distal surface) that is opposite to the surface in contact with the device (the proximal surface). The preferred embodiment uses commercially available Lumira Aerogel™ in particle or pellet form. The cooling pad is fabricated with the Lumira aerogel concentrated on the distal surface of the cooling pad. In addition, the proximal surface of the cooling pad preferably has a metalized mylar or other foil to maximize heat transfer from the device to the cooling pad.

The cooling pad structure has a core layer of PCM material between the distal and proximal layers of the cooling pad. The core layer is fabricated from lightweight polyaniline, commercially available from Sigma-Aldrich™, and graphene nanoplatelets, commercially available from xGnP™.

The cooling pad can be attached to a device by any suitable means, such as adhesive, double stick tape, etc.

An optional feature of the invention provides an integrated liquid crystal thermometer that provides the user with the visual indication of the current temperature of the electronic device. Liquid crystal thermometers are commercially available from a wide variety of sources, and are typically encased in a plastic strip that changes color to indicate different temperature ranges. They provide an advantage in that they are small, thin, and lightweight. They can be integrated with the cooling pad or installed as a separate unit.

Having discussed the invention in general, we turn now to a detailed discussion of the figures.

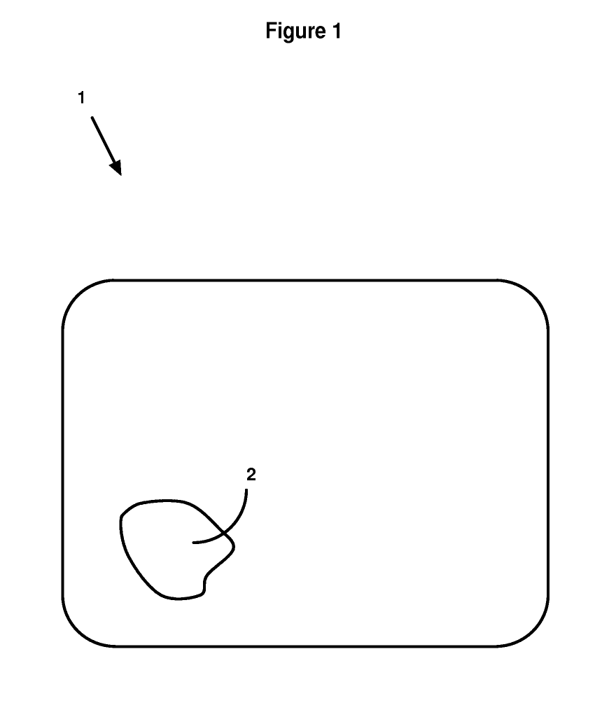

FIG. 1 illustrates a bottom plan view of a preferred embodiment of a laptop computer 1 showing a hot spot 2. Hot spots 2 can be caused by heat from the battery or other components of the computer that tend to produce excessive heat. While electronic devices need to operate within a predetermined temperature range, heat that will adversely affect a device's performance often is limited to a relatively small area of the device. As shown in this figure, the hot spot 2 is concentrated in only a portion of the tablet computer 1, but that is often all that is needed to cause device failure.

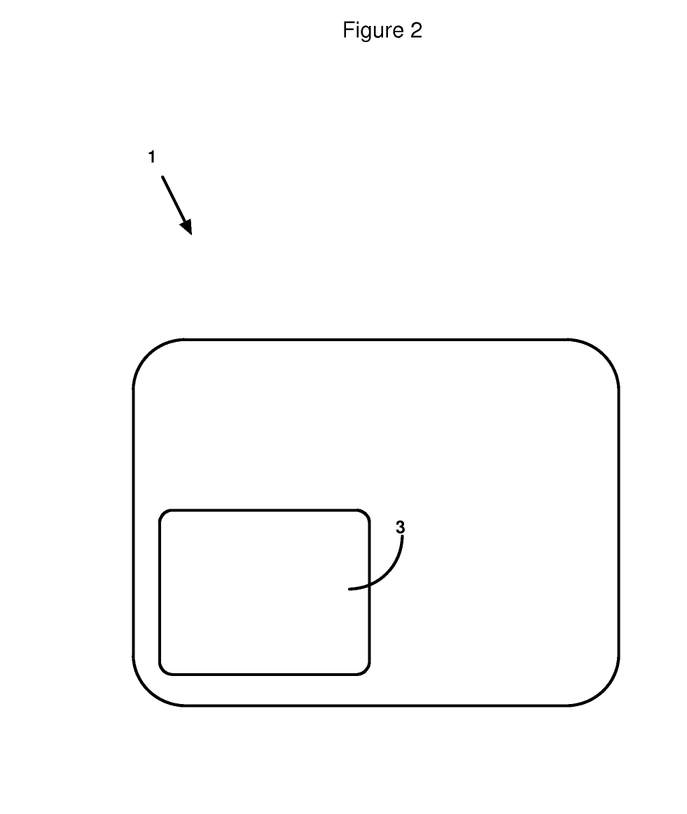

FIG. 2 illustrates a bottom plan view of a preferred embodiment of a laptop computer 1 showing a cooling pad 3 secured over the hot spot 2 (not shown in this figure). In this configuration, the cooling pad 3 draws heat from the hot spot 2, while the rest of the laptop computer 1, which is not excessively hot, does not require any thermal relief.

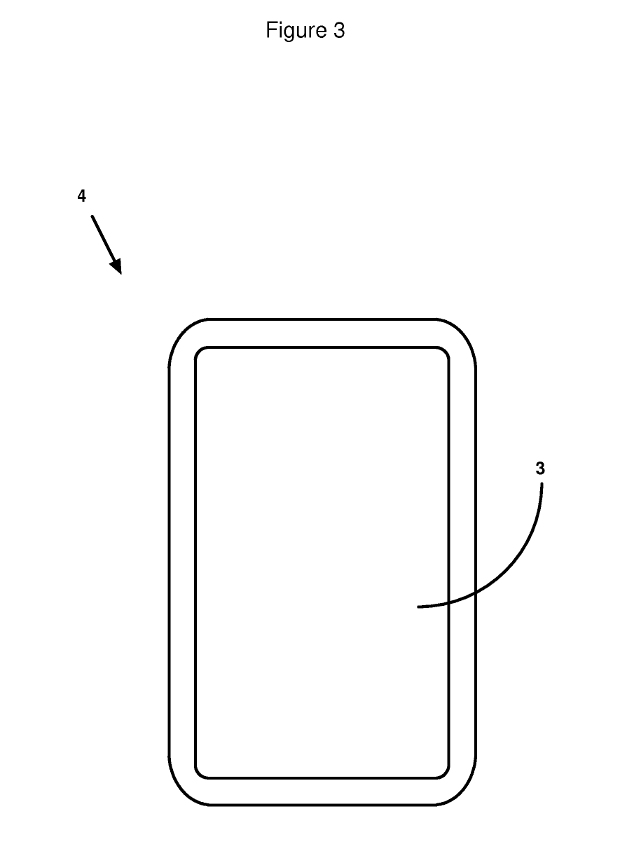

FIG. 3 illustrates a rear plan view of a preferred embodiment of a cellular phone 4 with a cooling pad 3 secured directly to its rear surface. An advantage of the invention is that the cooling pad 3 is thin enough that the cellular phone 4 can still be easily inserted into a protective cover such as those that are typically used by many cellular phone 4 users.

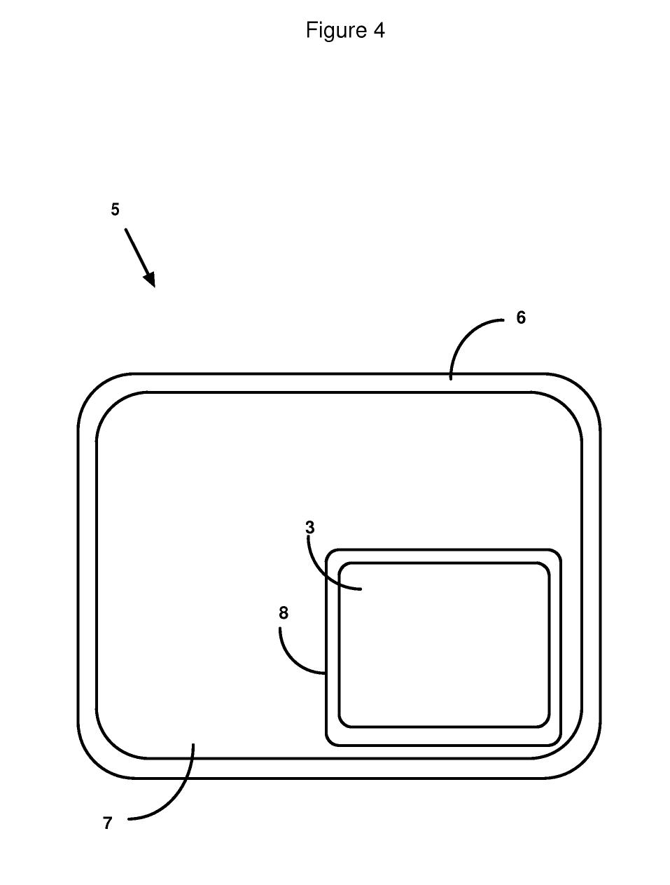

FIG. 4 illustrates another preferred embodiment showing a front view of a tablet cover 5 with a cooling pad 3 secured to the tablet cover 5 such that it is held in contact with the rear surface of the tablet computer 1 when the tablet computer 1 is placed in the tablet cover 5. The cooling pad 3 can be secured directly to the tablet cover 5, or alternatively, a thin layer of pliant material 8 can be used to form a pocket that holds the cooling pad 3.

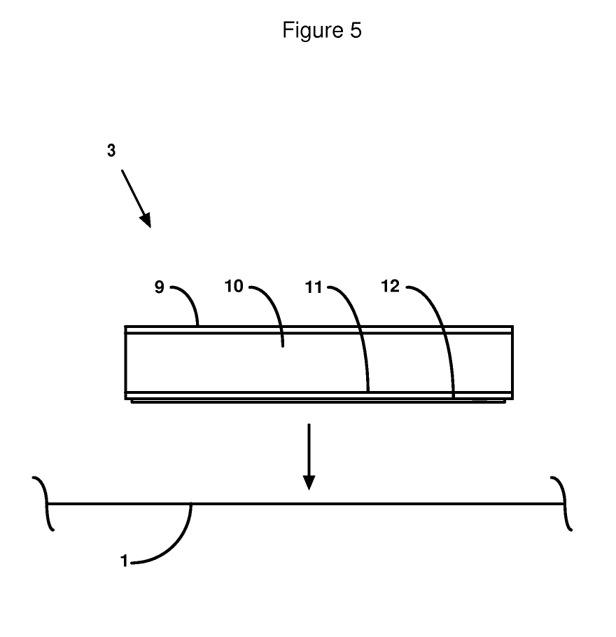

FIG. 5 illustrates an edge view of a preferred embodiment of the cooling pad 3 showing the layered structure. The insulation layer 9 is shown on the distal surface of the cooling pad 3. Beneath that is the core layer 10 that absorbs heat from the device 1. On the proximal surface of the cooling pad 3 is the heat transfer layer that can be a metalized mylar or other foil 11 to maximize heat transfer between the device 1 and the core layer 10.

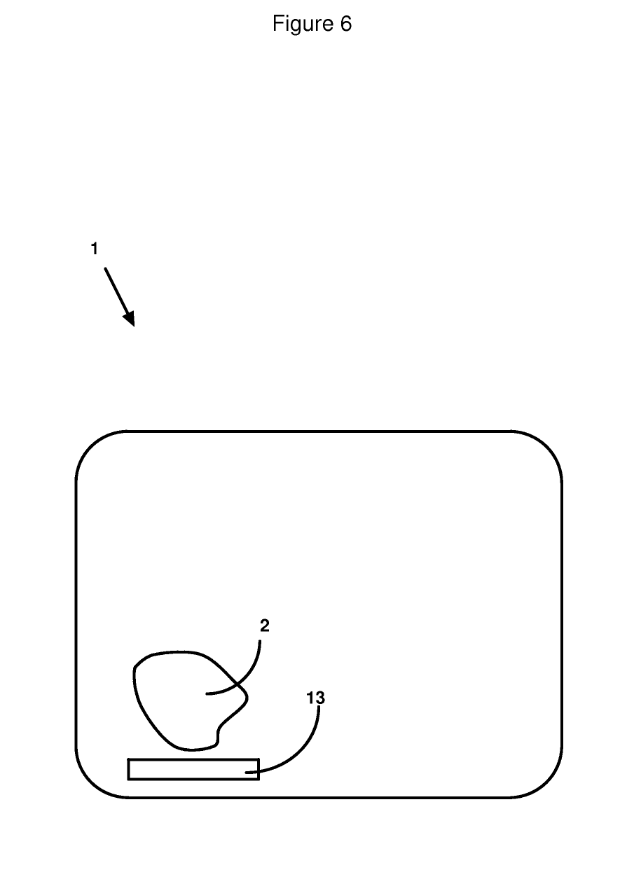

FIG. 6 illustrates a rear view of a device 1 with a thermal strip 13 for indicating the temperature of the device 1 at a location that is prone to heat. This figure shows the thermal strip secured directly to the surface of the device 1. This allows the thermal strip 13 to be permanently mounted to the device 1. However, those skilled in the art will recognize that the thermal strip 13 could also be integrated with the cooling pad 3.

While specific embodiments have been discussed to illustrate the invention, it will be understood by those skilled in the art that variations in the embodiments can be made without departing from the spirit of the invention. The types of materials used can vary, the method of attachment can vary, etc. For example, the phase change material can be any PCM material and does not have to be limited to the particular PCM material used above. The material used to fabricate the insulating layer and the heat transfer layer can vary. Therefore, the invention shall be limited solely to the scope of the claims.

I claim:

1. A detachable cooling pad for extracting heat from a battery in an electronic device, comprising:
a detachable cooling pad sized to secure to the cover of an electronic device above the location of the battery, such that heat is transferred from the battery to the detachable cooling pad, the detachable cooling pad further comprising at least a core layer comprised of heat absorbing material;
the detachable cooling pad having a proximal surface facing toward the device and a distal surface facing away from the device;
an attachment layer to removably secure the detachable cooling pad to the electronic device;
whereby the core layer extracts excessive heat from the battery on the device.

2. A cooling pad, as in claim 1, wherein:
the core layer is comprised of phase change material.

3. A cooling pad, as in claim 2, further comprising:
a distal layer secured to the distal surface of the core comprised of insulating material.

4. A cooling pad, as in claim 2, further comprising:
a proximal layer secured to the proximal surface of the core comprised of thermally conductive material.

5. A cooling pad, as in claim 4, wherein:
the proximal layer is comprised of metalized Mylar.

6. A cooling pad, as in claim 4, wherein:
a distal layer secured to the distal surface of the core further comprises insulating material.

7. A cooling pad, as in claim 6, wherein:
the insulating material in the distal layer further comprises Lumira Aerogel.

8. A cooling pad, as in claim 2, wherein:
the phase change material in the core layer further comprises graphine nano-platelets and polyaniline material.

9. A cooling pad, as in claim 8, further comprising:
a proximal layer comprised of thermally conductive material.

10. A cooling pad, as in claim 9, wherein:
the proximal layer further comprising metalized Mylar.

11. A cooling pad, as in claim 9, wherein:
a distal layer comprised of insulating material.

12. A cooling pad, as in claim 11, wherein:
the insulating material in the distal layer is comprised of Lumira Aerogel.

13. A cooling pad, as in claim 1, further comprising:
a pocket secured to the device to secure the cooling pad to the surface of the device.

14. A cooling pad, as in claim 1, further comprising:
an adhesive layer on the proximal surface of the cooling device to removably secure the cooling pad to the surface of the device.

15. A cooling pad, as in claim 1, further comprising:
a thermal strip secured to the device near the battery to indicate the temperature on the surface of the device.

16. (canceled)

17. (canceled)

18. (canceled)

19. (canceled)

20. (canceled)
